(19) United States
(12) Patent Application Publication
(10) Pub. No.: US 2006/0000501 A1
(43) Pub. Date: Jan. 5, 2006

(54) Solar oven (cooker & heater)

(76) Inventor: Nemat Ghausi, Elk Grove, CA (US)

Correspondence Address: Nemat Ghausi, 3121 Harbour Shore Lane, Elk Grove, CA, 95758, US

(21) Appl. No.: 10/884,814

(22) Filed: Jul. 2, 2004

(51) Int. Cl. H01L 35/00

(52) U.S. Cl. 136/206

(57) ABSTRACT

The Solar oven is using a solar radiation collection system and a photovoltaic heating system. The solar radiation collection panels heat the oven from the top. The photovoltaic system with its controls provides heat from the bottom. The system consists of a main primary radiation reflector at the top of the oven. The photovoltaic system consists of a solar panel charges the battery which in turn provides power to the heating element. The heating element is controlled to provide heat at the bottom for specified time limits and/or the specified amount of heat required for specific cooking or heating. A car electric generating system could also be used to provide power to the heating element. The system is design to be stationary or portable.

The Solar oven is economical, easy to build and to use. It consists of 1) solar radiation reflectors on the top of the solar oven. 2) The solar oven box which keeps and maintains the energy collected. 3) The photovoltaic heat and energy producing system. The solar radiation reflector or reflectors are made from reflective materials such as mylar, polished metals, mirror or reflective films. The reflectors provide solar energy from the top to the solar oven.

The solar oven consists of a box that keeps and maintains the collected energy. The top of the box is a thermal pane glass to keep the heat from escaping. The interior of the box is painted with heat absorbing material. The exterior of the box is insulated to keep the collected heath.

The photovoltaic system consists of a heating element at the bottom of the solar oven. The heating element is connected to a receptacle to receive power from the battery. The receptacle, the on/off switch, and controls for the amount of power are accessible from the outside of the box. The solar panel charges a battery that in return supplies power to the heating element. The on/off switch is used to provide power only when it is needed. The solar panel provides constant charge for the battery so the battery is fully charge even when the heating element is not in use.

The heating element provides uniform temperature to the oven. In a conventional sun oven, when baking a loaf of bread, the top of the loaf is baked well from the energy of the reflectors and usually the center of the loaf is not cooked or not cooked uniformly. The heating element provides the heat for even baking.

### BACKGROUND OF INVENTION

The system is one of the most economical methods for baking and cooking. The reflectors and the photovoltaic system both harness energy from the sun.

Most of the related US patents are based on harnessing the energy from the sun at the top of the oven by means of parabolic dish type collectors or other types to collect solar radiation.

U.S. Pat. No. 4,841,946 to Marks discloses dish type solar collector an heater and the movements of the unit is controlled electronically.

U.S. Pat. No. 3,938,497 to Andrassy discloses a moveable apparatus to find a favorable position of the sun. Likewise U.S. Pat. No. 4,111,184 discloses how a parabolic reflector is adjusted to the sun.

U.S. Pat. No. 4,249,511 to Krisst et al. discloses a parabolic dish reflector which acts as a grill in focal point.

U.S. Pat. No. 4,696,285 to Zwach discloses a primary and a secondary parabolic dish which reflect the radiation from the top.

U.S. Pat. No. 4,848,320 to Burn et al. discloses a collapsible reflector with a self-leveling tray to keep the food level within the interior of the oven.

### SUMMARY

The design is a solar heating and cooking system that uses both reflectors and a photovoltaic system. The photovoltaic system consists of a solar panel or panels, a battery or batteries and heating elements. The design provides a uniform heat for baking or cooking system. While the reflector energy bakes or cooks from the top, the heating element bakes and cooks from the bottom.

### BRIEF DESCRIPTION OF THE DRAWINGS

FIG. 1 show the of operation of solar oven with a photovoltaic system.

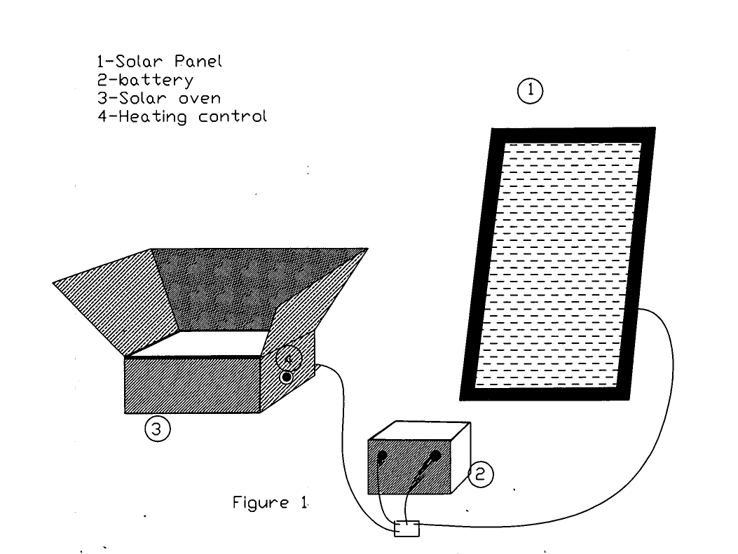

What is claimed is:

1- The use of photovoltaic system with a Solar Oven.

2- The system consists of a sun oven with reflectors, that reflect radiation to the box. The box is insulated and maintains the energy it receives. The thermal pane glass on top will prevent energy from escaping from the top.

3- The system in claim 1, accepts any solar oven with various reflector designs.

4- The system in claim 1, accommodates the use of various photovoltaic systems. The solar panel charges the batteries and the batteries in turn provides power to the heating element.

5- The system in claim 1 accommodates any photovoltaic system with various voltage range from 6 Volt to 220 volts with matching circuits and one or more heating elements.

6- The electronic circuits control duration and amount of energy supplied to the heating element.

7- The heating element provides additional energy to the solar oven and allows to heat from the bottom for an even baking temperature.

8- The system in claim 1 is accommodating multiple solar panels and multiple batteries.

9- The photovoltaic system in claim 1 could be used as sole provider of energy for the solar oven or for any even with proper heating elements, to be used indoors.

10- The system in claim 1 is accommodating multiple heating elements.
